(19) United States
(12) Patent Application Publication
(10) Pub. No.: US 2024/0183899 A1
(43) Pub. Date: Jun. 6, 2024

(54) TESTING OF ELECTRONIC EQUIPMENT

(71) Applicant: Total Quality Systems, Roy, UT (US)

(72) Inventors: Bryan Steadman, Farr West, UT (US); Leon Dennis, Roy, UT (US); Paul Hooper, Hooper, UT (US); Floyd Berghout, Logan, UT (US); Kirk Schmierer, Layton, UT (US); Robert Watson, Plain City, UT (US)

(73) Assignee: Total Quality Systems, Roy, UT (US)

(21) Appl. No.: 18/531,429

(22) Filed: Dec. 6, 2023

Related U.S. Application Data
(60) Provisional application No. 63/386,177, filed on Dec. 6, 2022.

(51) Int. Cl. G01R 31/28; G01R 31/30

(52) U.S. Cl. CPC G01R 31/2877; G01R 31/2881; G01R 31/3004

(57) ABSTRACT

Described herein are examples of a system, composed of a unique combination and/or customization of subsystems, components and methods of measuring detecting, isolating, and analyzing continuous and intermittent electromechanical failures in vehicle electronics interconnections equipment by applying relevant environmental forces to replicate operational stressors on electronics interconnection equipment to rigorously and exhaustively reproduce failures as if in operational use so that they may be identified, located, and repaired. As environmental stressors are applied, testing failure data is produced by measuring variances of expected voltages across conductive paths, with or without components, of the electromechanical equipment. The system produces comprehensive analyses, reports on all failure indications supported by heuristics, and statistics and applies machine learning techniques of each failure of each serial numbered UUT over time to improve the operational reliability of systems.

### CROSS-REFERENCE TO RELATED APPLICATIONS

The present application claim priority to U.S. Provisional Patent Application No. 63/386,177 entitled “SYSTEM OF ADVANCED DETECTION, ISOLATION, AND ANALYSIS OF ELECTROMECHANICAL FAILURES IN ELECTRONIC ASSEMBLIES UNDER OPERATIONAL ENVIRONMENTAL STIMULUS”, filed on Dec. 6, 2022. The entire contents of the above-listed application are hereby incorporated by reference for all purposes.

### BACKGROUND

The U.S. Department of Defense (“DoD”) spends billions of dollars in ineffective depot testing of aerospace, ground, surface, and subsurface vehicle electronics interconnection equipment. Most DoD automated test equipment functional evaluation processes are conducted in an office environment, with controlled temperature and humidity, and on a standard workbench (without any vibration), which can render inaccurate and ineffective results (e.g., Can Not Duplicate (CND) or Re-Test Ok (RTOK)) due to intermittent electromechanical failures in connectivity only occurring under operationally relevant environmental stressors.

### BRIEF DESCRIPTION OF THE DRAWINGS

The present description will be understood more fully when viewed in conjunction with the accompanying drawings of various examples of a testing of electromechanical equipment with environmental stimulus. The description is not meant to limit the testing of electromechanical equipment with environmental stimulus to the specific examples. Rather, the specific examples depicted and described are provided for explanation and understanding of testing of electromechanical equipment with environmental stimulus. Throughout the description, the drawings may be referred to as drawings, figures, and/or FIGs.

FIG. 1 illustrates topside view of a system of advanced detection, isolation, and analysis of electromechanical failures in electronic assemblies under operational environmental stimulus, according to an embodiment.

FIG. 2 illustrates topside view of a system of advanced detection, isolation, and analysis of electromechanical failures in electronic assemblies under operational environmental stimulus, according to an embodiment.

FIG. 3 illustrates a perspective view of the system, according to an embodiment.

FIG. 4 illustrates a block diagram of a method of present invention, according to an embodiment.

FIG. 5 illustrates a Pareto-type chart of Intermittent Failure Detections display, according to an embodiment.

### DETAILED DESCRIPTION

A testing of electromechanical equipment with environmental stimulus as disclosed herein will become better understood through a review of the following detailed description in conjunction with the figures. The detailed description and figures merely provide examples of the various embodiments of testing of electromechanical equipment with environmental stimulus. Many variations are contemplated for different applications and design considerations; however, for the sake of brevity and clarity, all the contemplated variations may not be individually described in the following detailed description. Those skilled in the art will understand how the disclosed examples may be varied, modified, and altered, and not depart in substance from the scope of the examples described herein.

The Department of Defense (“DoD”) conducts testing of aerospace, ground, surface, and subsurface vehicle electronics interconnection equipment at the Field-, Intermediate-, and Depot-level. Conventional DoD automated test equipment/systems (ATE or ATS) functional evaluation processes may be conducted in an office environment, with controlled temperature and humidity, and on a standard workbench without any vibration, which can render inaccurate and ineffective results, such as Can Not Duplicate (CND) or Re-Test Ok (RTOK), due to intermittent electromechanical failures in connectivity only happening under operationally relevant environmental stressors. Conventional electronics automated test systems do not include environmental stimulation as an integrated part of vehicle electromechanical interconnections testing, and therefore these conventional systems can result in inaccurate results. Namely, vehicle equipment which would otherwise indicate a fault in operational use could pass in such a traditional system as fully functional or otherwise register no failure.

When considering G-Force, vibration, and/or wide temperature fluctuations (for example, from 100 degrees Fahrenheit on the ground to −30 degrees Fahrenheit at 30,000 ft above ground level within a short span of time) given the time intervals at which equipment is expected to remain operative, current testing environments fail to consider all these test variables. There needs to be an integrated, easy-to-use method and system for testing electromechanical equipment interconnections in operational environments similar to the ones in which such equipment have experienced intermittent failures (indicated by vehicle Built-In Test (BIT) or ATE/ATS fault reports), especially with the fidelity and resolution needed to support troubleshooting modern high-speed (1 MHz and higher) electronics which indicate faults at nanosecond time scales. The problem, and thus the immense cost expenditure taken on by the DoD, for example, lies in the fact that vehicle electronics interconnections equipment is not being tested with these environmental factors in mind after a registered fault, and thus electronics interconnections equipment without such a system are not being tested with 100% coverage. Vehicle electronics interconnections equipment is being re-issued as “fully functional”, after testing in a static, room temperature environment, and are being sent back to aircraft or other vehicles for further use, and subsequently producing the same fault indication again in use. This insufficient test coverage issue ultimately fails to address the underlying electromechanical equipment intermittent electromechanical failures of its interconnections. As a consequence, electronics interconnections equipment continues to be repaired with latent intermittent failures, leading to continued, and unresolved, functional fault indications during operational use. In addition, this re-testing and its supporting global logistics systems are expensive and time consuming.

The conventional testability gap and the high cost of lowered operational reliability electronics assemblies due to intermittent connectivity root cause(s), demands a more operationally realistic and wholistic process of testing electronics interconnections that more closely reflects their operational use environment (with vibration, thermal, and perhaps other environmental test stimulation) for the purpose of eliciting, identifying, and precisely locating intermittent connection failures.

The present disclosure seeks to address electronics interconnections equipment failures by applying operational environmental stimulation to the testing process. The addition of operational environmental stimulus imitates the conditions where the vehicle electronics interconnection failures originally occurred, and thus very thoroughly elicits the root cause of failure points and enables the isolation of the failures that current testing processes and equipment fail to identify. The present disclosure is directed to an integration of components and software for more rigorously testing electronics interconnection equipment in a representative operational environment and producing comprehensive characterization reports as to the intermittent failure points and root cause(s). Technicians report that having the identification of the exact physical failure point(s) as part of the vehicle electronics interconnections test results is highly desired information set to provide the technician that the industry currently is not capable of producing with an existing system. The present disclosure seeks to remedy the current ineffectiveness and gaps prevalent in the aerospace, ship, and other vehicles repair and overhaul industry.

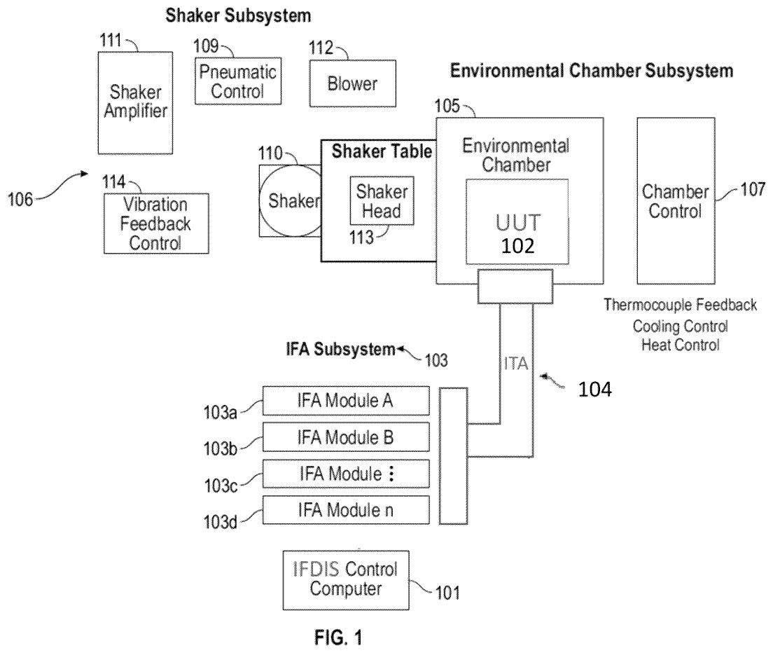

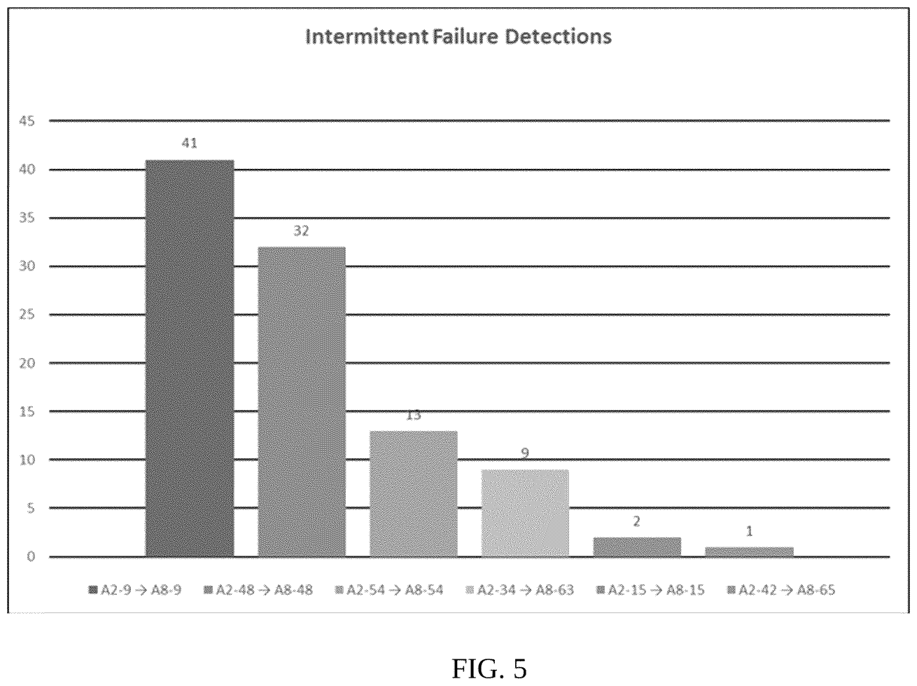

FIG. 1 illustrates an Intermittent Fault Detection and Isolation System (“IFDIS”) according to an embodiment. FIG. 1 further illustrates IFDIS Control Computer 101. The IFDIS system also detects constant (short circuits, or “shorts” and open circuits, or “opens”) as well as intermittent electromechanical discontinuities, isolates these failures to a specific location, and analyzes the digital circuitry response (implemented in hardware, software, and firmware). The IFDIS system integrates the capabilities needed to test and analyze a Unit Under Test (“UUT”) 102 under operationally-relevant use conditions. The IFDIS Control Computer 101 is the controlling device for all the IFDIS subsystems and provides the interface between the IFDIS and the operator. The operator selects the test to run from a menu on the IFDIS Control Computer's Graphical User Interface (GUI) displayed on a large monitor to initiate a controlled test sequence from the IFDIS Control Computer 101, to include ambient conditions if required, and then initiates the desired test. The operator executes and monitors the results of the tests (see below at FIG. 5), which are displayed on a monitor, and the system stores the test data in a central database on a computer. The IFDIS further serves as a digital database for collection and storage of detected and isolated failure data in digital formats for advanced post-test analysis and historical trend monitoring.

The IFDIS Control Computer 101 processes intermittent events received from the Intermittent Failure Analyzer 103 (“IFA”) testing subsystem along with the vibration and thermal conditions present when the intermittent event occurred.

The IFA 103 is located in the equipment cabinet which uses IFDIS Control Computer running proprietary software and FA 103 circuitry installed into equipment racks called IFA Modules 103a-d, each containing two-hundred and forty (240) test points. The IFA 103 assembly can have multiple IFA Modules 103a-n. IFA Modules 103a-n can be interfaced together to provide tens of thousands test capacity, or more.

In an embodiment, the IFA 103 monitors the connectivity of every conductive path in the UUT to be tested by the IFDIS. A low level of voltage is injected across every conductive path wherein the voltage potential is measured by the IFA 1.03 to determine deviations from the expected value continuously and simultaneously during a UUT-specific environmental test profile. If the voltage deviates a certain percentage from expected values (adjusted for external noise, as needed), the IFA 103 signals the IFDIS control computer 101 which prompts the Graphical User Interface (GUI) with an alert indicating failure detection (see FIG. 5 below), isolated to a single circuit, and records the related failure event data (such as a graph of the recorded voltage over time, date/time, operator, serial number of the UUT, test location, and/or other data) in the IFDIS 101 control computer database.

The Interface Test Adapter 104 (“ITA”) is a custom multi-cable assembly which connects the IFA Modules 103a-d to each unique UUT 102 type and enables communication between the IFA 103 and the test circuits in the UUT 102. Specialized cables, connectors, and fixtures, along with standard connectors and cables, are integrated and used to make the ITA 104. The ITA acts as an inimitable interface adaptor to connect a certain UUT type to the system for testing. Each UUT type contains a unique design set of circuits, and each UUT uses unique connectors, thus the ITA must be tailored to each UUT type—number of circuits, input connectors, output connectors, arrangement of ITA wires (for fit and function), and/or cable length.

The system, in an embodiment, measures and detects steady-state electromechanical conductivity and intermittent electromechanical conductivity degradation of passive resistive paths, to include inline passive components. A custom, UUT-specific shaker hold-down fixture is also part of this ITA equipment, as well as operator tools to attach/detach the ITA.

The system, in an embodiment, receives input regarding relevant test parameters and transfers the test parameters to the operative detection and isolation subsystem.

The system in an embodiment, conducts simultaneous real-time automated measurements of an amass of conductive paths within a UUT 102 to detect electromechanical failure events as they present themselves.

The system, in an embodiment, provides adjustments to measured Signal-to-Noise Ratio (SNR) sensitivity (or adjusting measured signal-to-noise ratio sensitivity) based on external environment electromagnetic field ratios.

The system, in an embodiment, performs automated algorithms of the measurement results to identify, isolate, and characterize electromechanical failure modes, including a mode to isolate electromechanical failures to a single circuit, with associated test points identified graphically to the technician.

The system, in an embodiment, implements advanced digital signal processing techniques to analyze the failure mode, including: signal response shape analysis, comparative analysis, historical analysis, and trend analysis by UUT serial number and/or UUT type. In addition, advanced digital signal processing techniques are implemented to reduce the effect of background electrical and magnetic field effects on measurements to reduce false positive indications.

The system, in an embodiment, provides provisions for failure isolation techniques, including: i. adaptive directive current flow through a single or multiple UUT circuits; ii. voltage differential analysis of UUT conductor paths; and iii. manual and/or automatic probing and analysis of UUT circuits to precisely locate an electromechanical failure in a circuit path.

The system, in an embodiment, collects test results (multiple digital formats), including: failure detection, failure location, and failure response data a particular and exact failed circuit path of a UUT 102 for the purpose of visualization display of results to an operator in near-real-time (see FIG. 5 below).

The system, in an embodiment, captures and collects electromechanical failures detected and isolated from an amass of UUT 102 circuits as a result of the testing process for the purpose of providing long-term tracking of the health of UUTs and their internal circuit paths over time, including: i. failure severity monitoring; ii. failure trend data, iii. organizes and tags collected results data with the various metadata UUT including serial number, UUT model number, operator identification code, operator geographic location and assignment, time/date at the time of event detection, and environmental stimulus applied at the time of detection.

The system, in an embodiment, uses machine learning via a classifying engine, to support the characterization, analysis, categorization, and/or cataloging of electromechanical failures (or electromechanical failure mode) of a particular circuit of a UUT over time, including: the number of electromechanical failure modes detected, ambiguity group of electromechanical failure modes isolated, analysis of electromechanical failure modes, electromechanical failure trends, and statistical analysis of the resulting information, including mean time between failures, Mean Cumulative Function, Bayesian predictive analysis, Condition-Based Maintenance, and/or other predictive maintenance algorithms known to those skilled in the an.

The integrated IFDIS Control Computer 101 is also used to control the overall test scenario. The operator uses this computer to initiate the IFDIS software program which issues commands to both the Environmental Chamber 105 and the Shaker Subsystem 106. IFDIS control computer 101, provides the capability to monitor the status of each operation in real-time on a large display monitor and provide feedback to the operator.

The Environmental Chamber 105 is a subsystem and consists of two primary units, the chamber itself, and an Environmental Chamber Control subsystem 107. The Environmental Chamber 105 provides an environment of varying temperatures. Cooling is provided by a self-contained two stage cascade refrigeration subsystem and is monitored and controlled from an HVAC Controller 107 located in the Environmental Chamber Control subsystem 107. Similarly, heat is controlled by the same integrated HVAC Controller, and is provided by large electrical resistance heating elements. During routine testing of the UUT 102, the chamber's ambient air temperature typically ranges from −40 degrees to +70 degrees C. (depending on UUT requirements). A safety shut down controller in the Environmental Chamber Control subsystem 107 initiates a safety shut down if the Environmental Chamber 105 temperature exceeds preset limits. A thermocouple temperature sensor can be attached to the UUT 102 via a hold down fixture (and/or other location(s)), when needed for more accurate localized temperature readings.

The Shaker subsystem 106 provides a defined profile of vibration stimulus to the UUT 102 during testing and consists of five primary pieces of equipment: the Shaker Controller, Shaker 110, Shaker Amplifier 111, Blower 112, and the Air Float subsystem 109. The Shaker Subsystem 106, in conjunction with the Environmental subsystem, acts as an environmental stimulation device (including the capability to test in three-axes for vibration (multiple profiles), shock, temperature, atmospheric pressure, and humidity).

The Shaker Controller 214 (which can also be referred to as a Vibration Controller) monitors the movement of the Shaker Subsystem 106 from accelerometers affixed to the Shaker Head Expander 113 and provides the vibration control feedback signal to the Shaker Amplifier 111. The Shaker Controller receives and processes: a) the vibration profile commands from the IFDIS control computer 101 and the b) feedback signal from the accelerometer on the Shaker 110. The Shaker Controller then processes the commands and feedback signals and provides the required input (i.e., “operational profile” of the UUT) to the Shaker Amplifier 111.

The Shaker 110 produces the physical movement profile over time that provides the vibration to the UUT 102. It includes the mounting platform, referred to as the Shaker Head Expander 113, to which is fastened the UUT 102 and the Shaker 110 for shaking as commanded by the IFDIS control computer 101 via UUT vibration test profiles. The Shaker Head Expander 113 is attached to an armature of the moveable Shaker 110. When a suitable level of alternating current is applied to the moveable armature, the interaction between the armature and the stationary field coil will cause the armature, and therefore, the Shaker Head Expander 113 and UUT 102, to vibrate up and down when precise and controlled high current is applied to the field coils. The Shaker 110 is moved in a manner similar to the voice coil in an audio speaker. The combined effect of this assembly is the ability to shake the UUT: 102 at the frequency, rate and G-Force as commanded by the IFDIS control computer 101. The custom Air Float System 109 is integrated into the base of the Shaker 110 and enables the Shaker 110 to be easily moved in and out of the Environmental Chamber 105 on a cushion of air, without presenting a tripping hazard such as rails on the floor would.

The Shaker Amplifier 111 receives the vibration command signal from the Shaker Controller 214, amplifies the signal, and provides the high current to the Shaker's 110 moveable armature coils. The Shaker Amplifier 111 also activates and deactivates the cooling Blower 112 for the Shaker 110. The Blower 112 provides the airflow required to keep the actuator of Shaker 110 cool during operation.

In an embodiment, the system includes a unit under test (connected to the system using an ITA 104), wherein the unit under test is an electromechanical device and the unit under test is submitted to environmental stimuli to simulate real-world events, e.g., speed, shock, weather, temperature, pressure, lightning, motion, and other environmental stimuli. The system further includes a control computer wherein the control computer is configured to process data associated with the unit under test, and wherein the control computer further includes a graphical user interface. The system includes an intermittent failure analyzer, wherein the intermittent failure analyzer is configured to test the unit under test, and the intermittent failure analyzer further includes digital electronic intermittent failure analyzer modules. The system includes an interface test adapter wherein the interface test adapter is configured to connect the unit under test to the intermittent failure analyzer. The system includes an environmental chamber wherein the environmental chamber is configured to provide environmental stimuli to the unit under test (UUT). The environmental chamber can further include an environmental chamber control subsystem; a refrigeration subsystem; a heating ventilation and cooling controller; a thermocouple temperature sensor; and a safety shut down controller. The system includes a shaker subsystem, wherein the shaker subsystem is configured to provide simulated motion to the unit under test, and wherein the shaker subsystem further includes a shaker controller; a shaker; a shaker head expander; a shaker amplifier; a blower; and air float subsystems. The system can further include an equipment cabinet wherein the equipment cabinet is configured to store equipment to test the unit under test. The equipment cabinet can further include a digital multimeter, an oscilloscope; a power conditioning equipment; an air filter; and cooling subsystems.

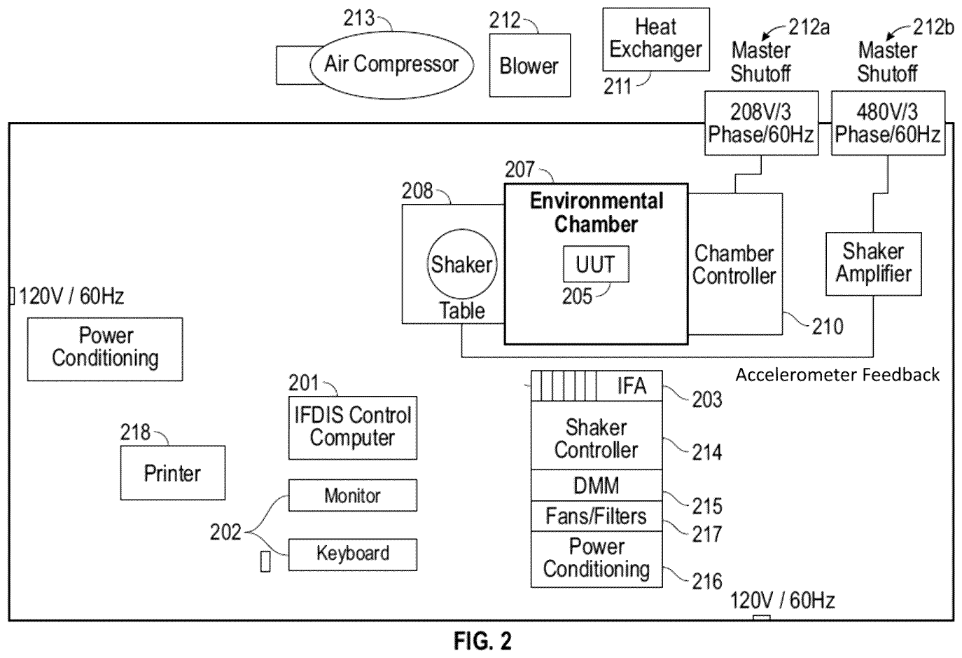

FIG. 2 illustrate an Intermittent Fault Detection and Isolation System (“IFDIS”) according to an embodiment. FIG. 2 further illustrate IFDIS Control Computer 201. The IFDIS system detects constant (short circuits, or “shorts” and open circuits, or “opens”) and intermittent electromechanical discontinuities, isolates these failures to a specific location, and analyzes the digital circuitry response (implemented in hardware, software, and firmware). The IFDIS system integrates the capabilities needed to test and analyze a Unit Under Test (“UUT”) 205 under operationally-relevant use conditions. The IFDIS Control Computer 201 is the controlling device for all the IFDIS subsystems and provides the user interface between the IFDIS and the operator. The operator selects the test to run from a menu on the IFDIS Control Computer's Graphical User Interface (GUI) displayed on a large monitor to initiate a controlled test sequence from the IFDIS Control Computer 201, to include ambient conditions if required, and then initiates the desired test. The operator executes and monitors the results of the tests, which are displayed on a monitor, and the system stores the resulting test data in a central database on a computer. The IFDIS further serves as a digital database for collection and storage of detected and isolated failure data in digital formats for advanced post-test analysis and historical trend monitoring.

The computer running the GUI can be of any standard operating system on any conventional PC that meets IFDIS specifications, which can be set up on a table as the working surface for the operator. Such a table would hold the control computer display monitor, and control devices (including keyboard, mouse, etc.), as well as the printer and any communications or network switches. A color printer 218 is provided with the IFDIS control computer 201 so that test results and other test system screen displays may be printed in color from the IFDIS control computer 201.

The IFDIS control computer 201 is communicatively coupled to the GUI. The operator typically uses a 55-inch class ultra-HD display but can be sized depending on the UUT's test point capacity and screen resolution requirements. A high-resolution graphic display is required to view small details in the graphics of large test point count UUT 205. The monitor displays the GUI that provides the software controls to operate the IFDIS control computer 201 as well as the test result details. The monitor displays intermittent events received from the Intermittent Failure Analyzer 203 (“IFA”) testing subsystem along with the vibration and thermal conditions present when the intermittent event occurred.

The IFA 203 is located in the equipment cabinet 305 which uses IFDIS Control Computer running proprietary software and IFA 203 circuitry installed into equipment racks called IFA Modules 103a-d, each containing two-hundred and forty (240) test points. The IFA 103 assembly can have multiple IFA Modules 103a-n. IFA Modules 103a-n can be interfaced together to provide tens of thousands test point capacity, or more.

In an embodiment, the IFA 203 monitors the connectivity of every conductive path in the UUT to be tested by the IFDIS. A low level of voltage is injected across every conductive path wherein the voltage potential is measured by the IFA 203 to determine deviations from the expected value continuously and simultaneously during a UUT-specific environmental test profile. If the voltage deviates a certain percentage from expected value for each circuit under test, the IFA 203 signals the IFDIS control computer 201 which prompts the Graphical User Interface (GUI) with an alert indicating failure detection, isolated to a single circuit, and records the related failure event data in a database of the IFDIS control computer 201.

The Interface Test Adapter 104 (“ITA”) is a custom multi-conductor cable assembly which connects the IFA Modules 103a-d to each unique UUT 205 type and enables communication between the IFA 203 and the test circuits in the UUT 205. Specialized cables, connectors, and fixtures, along with standard connectors and cables, are integrated and used to make the ITA 104. The ITA acts as an inimitable interface adaptor to connect a certain UUT type to the system for testing.

The integrated IFDIS Control Computer 201 is also used to control the overall test scenario. The operator uses this computer to initiate the IFDIS software program which issues commands to both the Environmental Chamber 207 and the Shaker Subsystem. IFDIS control computer 201, provides the capability to monitor the status of each operation in real-time on a large display monitor 202 and provide feedback to the operator.

The Environmental Chamber 207 is a subsystem and consists of two primary units, the chamber itself, and an Environmental Chamber Control subsystem 210. The Environmental Chamber 207 provides an environment of rapid varying temperatures. Cooling is provided by a self-contained two stage cascade refrigeration subsystem 211 and is monitored and controlled from an HVAC Controller 210 located in the Environmental Chamber Control subsystem. Similarly, heat is controlled by the same integrated HVAC Controller 210 and is provided by large electrical resistance heating elements. During routine testing of the UUT 205, the chamber's ambient air temperature typically ranges from −40 degrees to +70 degrees C. (depending on UUT requirements). A safety shut down controller 2109 in the Environmental Chamber Control subsystem 107 initiates a safety shut down if the Environmental Chamber 207 temperature exceeds preset limits. A thermocouple temperature sensor can be attached to the UUT 205 via a hold down fixture, when needed for more accurate localized temperature readings.

The Shaker subsystem provides a defined profile of vibration stimulus to the UUT 205 during testing and consists of five primary pieces of equipment: the Shaker Controller 214, Shaker 208, Shaker Amplifier, Blower 212, and the Air Float subsystems 213. The Shaker subsystem, in conjunction with the Environmental subsystem, acts as an environmental stimulation device (including the capability to test in three-axes for vibration, shock, temperature, atmospheric pressure, and/or humidity).

The Shaker Controller 214 (which can also be referred to as a Vibration Controller) monitors the movement of the Shaker 208 from accelerometers affixed to the Shaker Head Expander and provides the vibration control feedback signal to the Shaker Controller. The Shaker Controller 214 receives and processes: a) the vibration profile commands from the IFDIS control computer 201 and the b) feedback signal from the accelerometer on the Shaker 208. The Shaker Controller 214 then processes the commands and feeds back signals to provide the required input (i.e., “operational profile”) to the Shaker Amplifier.

The Equipment Cabinet 305 provides the housing for various subsystem equipment (the IFA Modules 103a-d, the Digital Multimeter 215 (DMM), and/or an oscilloscope) as well as provides electromagnetic interference protection. Power conditioning equipment 216 is mounted in this cabinet. Air filter/Cooling subsystems 217 are also mounted in the cabinet to service the equipment in the cabinet.

The Digital Multimeter (DMM) 215 is a multidigit precision voltage meter and is the device used to manually measure a single connection or path during a manual single channel test. It is not used during IFDIS Intermittent Testing, but can be used for further isolating failures after such testing. An oscilloscope is provided to manually characterize and better understand detected intermittent failures in more detail, if necessary.

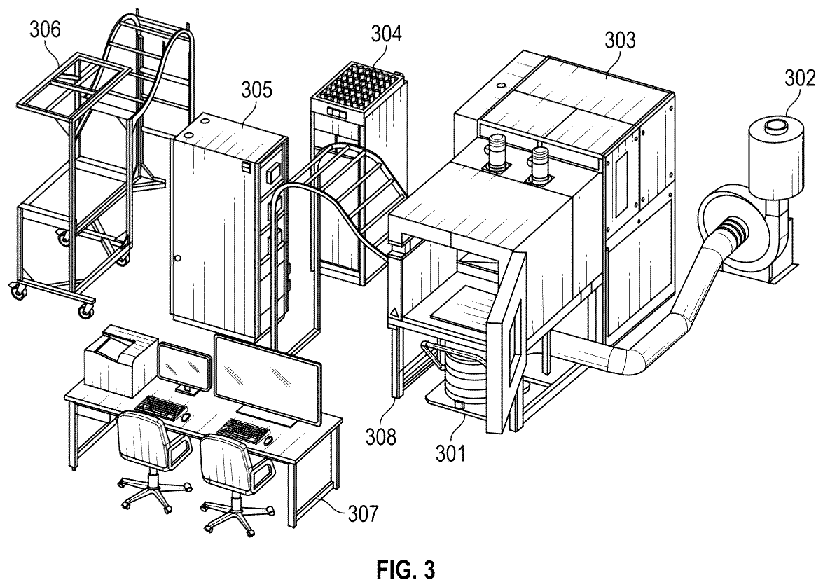

FIG. 3 is a perspective view of the IFDIS system showing the arrangement of subsystems, equipment, components, and hardware used by the system to accurately test, monitor, and record a UUT under simulated operational environmental stressors. Operational environmental stressors can include; G-Forces, vibration, and/or wide temperature fluctuations (simulating operational use, such as, 100 degrees Fahrenheit on the ground to −30 degrees Fahrenheit at 30,000 ft above ground level within a short span of time). These environmental stimuli or environmental stressors are used to test the electromechanical interconnections in electronic equipment for the purpose of detecting intermittent electromechanical failures in electrical circuitry which occur during operation. FIG. 3 illustrates the shaker 301 and the blower 302 connected to the environmental chamber 303. Additionally, control computer 101 and the equipment cabinet 305 are located near the environmental chamber 303 in the embodiment shown. An additional rack 306 suitable as an additional equipment cabinet or storage device is also illustrated in FIG. 3. Additionally, the graphical user interface is displayed as multiple screens that are capable of connection with the control computer to display real-time information to a user. Also shown in the embodiment is an ITA cart 306 (an ITA 104 is not shown in FIG. 3).

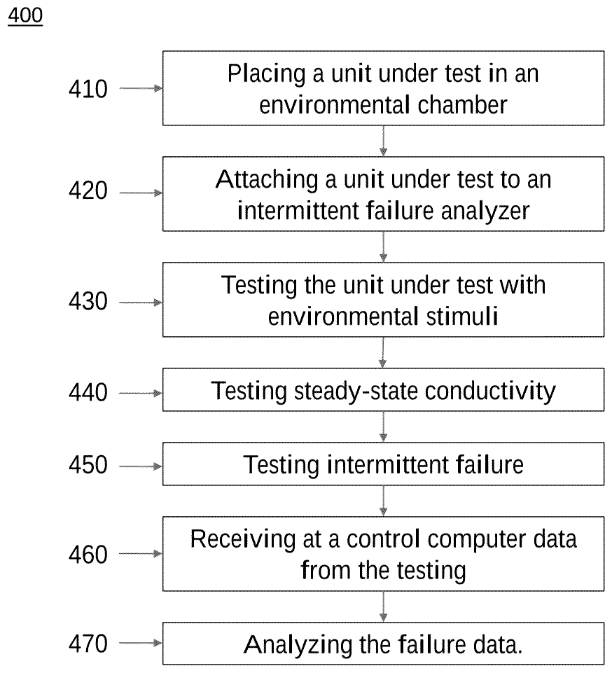

FIG. 4 is a block chart of a method 400 of the present invention according to an embodiment. The method 400 includes step 410 placing a unit under test in an environmental chamber wherein the environmental chamber includes an environmental chamber control subsystem, and a heating ventilation and cooling controller. Step 420 attaching the unit under test to an intermittent failure analyzer, wherein the unit under test is attached to the intermittent failure analyzer via an interface test adapter, and wherein the intermittent failure analyzer further comprises intermittent failure analyzer modules. Step 430 testing the unit under test with environmental stimuli wherein the environmental stimuli are provided via environmental chamber and shaker subsystems. Wherein the shaker subsystem further includes a shaker controller, a shaker, and a shaker head expander. Step 440 is testing for steady-state conductivity issues, such as short and/or open circuits, without environmental stimulus. Step 450 includes environmental stimulus to detect and isolate intermittent conductivity failures. Step 460 includes receiving, at a control computer, data from the testing (Step 440 and/or 450), wherein the data is processed in the control computer and provided to a user via a graphical user interface. During a three-hour environmental stimulation test session, the data accumulated can be in excess of 1 terabyte. Step 470 analyzes the data to identify and locate the failure mode, and well as trends over time.

Steady state open and short circuit failures can be detected, captured and recorded before environmental stimulus is applied. Steady state out-of-bounds events are triggered and captured based on engineered values of an upper and a lower voltage for each circuit determined by the steady state characteristic of each circuit. An event can be a voltage outside of upper limit or lower limit range, such as an engineering-derived value based on the characteristics of the circuit (e.g., a wire can include a resistor or other passive component, divides voltage based on parallel paths, supports high-speed digital signals, etc.).

Intermittent shorts can be detected by monitoring all circuits continuously during the test for anomalous voltages as one circuit conductively touches another, then that anomalous voltage can be observed and recorded as an event of interest. Environmental stimulus (vibration, shock, temperature, and/or humidity) can be applied during this test process. When a response signal (voltage over time) is detected to be outside of lower or upper voltage acceptable range, an event is triggered. An event can be a voltage outside of upper limit or lower limit range, such as an engineering-derived value based on the characteristics of the circuit (e.g., a wire can include a resistor or other passive component, divides voltage based on parallel paths, supports high-speed digital signals, etc.).

Intermittent opens can be detected by monitoring all circuits for anomalous voltage drops as a circuit(s) conductively disconnects, then that voltage drop can be observed and recorded as an event of interest and recorded. Environmental stimulus (vibration, shock, temperature, and/or humidity) are applied during this test process. When a response signal (voltage over time) is detected to be outside of lower or upper voltage acceptable range, an event is triggered. An event can be a voltage outside of upper limit or lower limit range, such as an engineering-derived value based on the characteristics of the circuit (e.g., a wire can include a resistor or other passive component, divides voltage based on parallel paths, supports high-speed digital signals, etc.).

Monitoring channels use digital addressing to continuously stimulate and record every circuit. Monitoring channels can reverse the direction of current flow to test diodes or other characteristics of each circuit of interest. Monitoring channels can have set delays to account for settling of the test signal for the purposes of testing capacitors, inductors and certain characteristics of each circuit of interest. Time-phased event detection can occur at 50 nanosecond intervals (or less) on all monitored circuits simultaneously and continuously.

The present invention can analyze failure indication via digital signal processing including the combination of: signal response location, identification and/or syntax; signal response characterization (shape, magnitude, and/or duration); signal response analysis (time domain, energy displacement, and/or severity); classification and categorization of the characterized parameters of the response; comparative analysis (by shape, magnitude, and/or duration); historical analysis (of UUT serial number, type, and/or family); or trend analysis over time (by serial number, by family, system number, operator, operational location and/or maintenance procedure). The present invention can further generate electromechanical root cause failure isolation indication(s); generates and records the test results outcome; and produces the test results outcome, to include a failure indication, a failure indication isolation solution; and the test outcome on a user interface.

Embodiments of the present invention can include a test subsystem analyzer, wherein, multiplexed, high-speed Analog-to-Digital Converters (ADCs), one for each monitored circuit are connected to a UUT via an ITA. A computer subsystem hosting proprietary computer software, including a Central Master CPU with custom firmware to synchronize the network, collect data from each circuit channel, and transfer data to a personal computer and its hosted database.

FIG. 5 illustrates a Pareto-type chart of Intermittent Failure Detections. As shown in FIG. 5, the most intermittently connected circuit is displayed on the left-most side of the graph (in this case, the circuit beginning at UUT point connector two, pin nine (A2-9) and terminating at A8-9). The lesser event detected circuit is displayed to its right, and so on, along the x-axis. The number of detected ‘out-of-bounds’ events is listed at the top of each graphical column. The column heights are indicative of the number of events detected of each circuit, and horizontal lines on a y-axis scale depicts that magnitude in scale. The UUT type, serial number, and test date are displayed at the top of the graph, just under the test tile (“intermittent Failure Detections”). The graph can scale to the number of circuits with intermittent continuities, as required.

After testing, an analysis of the measured response curves and other data can be compared and contrasted against expected response outputs and other historical records (a database storage of event packet data of response waveform collections). Post-analysis (such as waveform and statistical analysis) can then be displayed in human interpretable format on the IFDIS Control Computer screen.

A feature illustrated in one of the figures may be the same as or similar to a feature illustrated in another of the figures. Similarly, a feature described in connection with one of the figures may be the same as or similar to a feature described in connection with another of the figures. The same or similar features may be noted by the same or similar reference characters unless expressly described otherwise. Additionally, the description of a particular figure may refer to a feature not shown in the particular figure. The feature may be illustrated in and/or further described in connection with another figure.

Elements of processes (i.e., methods) described herein may be executed in one or more ways such as by a human, by a processing device, by mechanisms operating automatically or under human control, and so forth. Additionally, although various elements of a process may be depicted in the figures in a particular order, the elements of the process may be performed in one or more different orders without departing from the substance and spirit of the disclosure herein.

The foregoing description sets forth numerous specific details such as examples of specific systems, components, methods and so forth, in order to provide a good understanding of several implementations. It will be apparent to one skilled in the art, however, that at least some implementations may be practiced without these specific details. In other instances, well-known components or methods are not described in detail or are presented in simple block diagram format in order to avoid unnecessarily obscuring the present implementations. Thus, the specific details set forth above are merely exemplary. Particular implementations may vary from these exemplary details and still be contemplated to be within the scope of the present implementations.

Related elements in the examples and/or embodiments described herein may be identical, similar, or dissimilar in different examples. For the sake of brevity and clarity, related elements may not be redundantly explained. Instead, the use of a same, similar, and/or related element names and/or reference characters may cue the reader that an element with a given name and/or associated reference character may be similar to another related element with the same, similar, and/or related element name and/or reference character in an example explained elsewhere herein. Elements specific to a given example may be described regarding that particular example. A person having ordinary skill in the art will understand that a given element need not be the same and/or similar to the specific portrayal of a related element in any given figure or example in order to share features of the related element.

It is to be understood that the foregoing description is intended to be illustrative and not restrictive. Many other implementations will be apparent to those of skill in the art upon reading and understanding the above description. The scope of the present implementations should, therefore, be determined with reference to the appended claims, along with the full scope of equivalents to which such claims are entitled.

The foregoing disclosure encompasses multiple distinct examples with independent utility. While these examples have been disclosed in a particular form, the specific examples disclosed and illustrated above are not to be considered in a limiting sense as numerous variations are possible. The subject matter disclosed herein includes novel and non-obvious combinations and sub-combinations of the various elements, features, functions and/or properties disclosed above both explicitly and inherently. Where the disclosure or subsequently filed claims recite “a” element, “a first” element, or any such equivalent term, the disclosure or claims is to be understood to incorporate one or more such elements, neither requiring nor excluding two or more of such elements.

As used herein “same” means sharing all features and “similar” means sharing a substantial number of features or sharing materially important features even if a substantial number of features are not shared. As used herein “may” should be interpreted in a permissive sense and should not be interpreted in an indefinite sense. Additionally, use of “is” regarding examples, elements, and/or features should be interpreted to be definite only regarding a specific example and should not be interpreted as definite regarding every example. Furthermore, references to “the disclosure” and/or “this disclosure” refer to the entirety of the writings of this document and the entirety of the accompanying illustrations, which extends to all the writings of each subsection of this document, including the Title, Background, Brief description of the Drawings, Detailed Description, Claims, Abstract, and any other document and/or resource incorporated herein by reference.

As used herein regarding a list, “and” forms a group inclusive of all the listed elements. For example, an example described as including A, B, C, and D is an example that includes A, includes B, includes C, and also includes D. As used herein regarding a list, “or” forms a list of elements, any of which may be included. For example, an example described as including A, B, C, or D is an example that includes any of the elements A, B, C, and D. Unless otherwise stated, an example including a list of alternatively-inclusive elements does not preclude other examples that include various combinations of some or all of the alternatively-inclusive elements. An example described using a list of alternatively-inclusive elements includes at least one element of the listed elements. However, an example described using a list of alternatively-inclusive elements does not preclude another example that includes all of the listed elements. And, an example described using a list of alternatively-inclusive elements does not preclude another example that includes a combination of some of the listed elements. As used herein regarding a list, “and/or” forms a list of elements inclusive alone or in any combination. For example, an example described as including A, B, C. and/or D is an example that may include: A alone; A and B; A, B and C; A, B, C, and D; and so forth. The bounds of an “and/or” list are defined by the complete set of combinations and permutations for the list.

Where multiples of a particular element are shown in a FIG., and where it is clear that the element is duplicated throughout the FIG., only one label may be provided for the element, despite multiple instances of the element being present in the FIG. Accordingly, other instances in the FIG. of the element having identical or similar structure and/or function may not have been redundantly labeled. A person having ordinary skill in the art will recognize based on the disclosure herein redundant and/or duplicated elements of the same FIG. Despite this, redundant labeling may be included where helpful in clarifying the structure of the depicted examples.

The Applicant(s) reserves the right to submit claims directed to combinations and sub-combinations of the disclosed examples that are believed to be novel and non-obvious. Examples embodied in other combinations and sub-combinations of features, functions, elements and/or properties may be claimed through amendment of those claims or presentation of new claims in the present application or in a related application. Such amended or new claims, whether they are directed to the same example or a different example and whether they are different, broader, narrower or equal in scope to the original claims, are to be considered within the subject matter of the examples described herein.

1. A device comprising:
a control computer,
wherein the control computer is configured to process data associated with a unit under test,
wherein the unit under test is an electromechanical device; and
the unit under test is submitted to environmental stimuli to simulate real-world events;
wherein the control computer further comprises a graphical user interface;
an intermittent failure analyzer,
wherein the intermittent failure analyzer is configured to test the unit under test, and
the intermittent failure analyzer further comprises intermittent failure analyzer modules; and
attaches to a circuit of the electromechanical device;
an interface test adapter,
wherein the interface test adapter is configured to connect the circuit to the intermittent failure analyzer;
an environmental chamber,
wherein the environmental chamber is configured to provide environmental stimuli to the unit under test, and
wherein the environmental chamber further comprises:
an environmental chamber control subsystem;
a refrigeration subsystem;
a heating ventilation and cooling controller;
a thermocouple temperature sensor; and
a safety shut down controller; and
a shaker subsystem,
wherein the shaker subsystem is configured to provide simulated motion to the unit under test,
wherein the shaker subsystem further comprises:
a shaker;
a shaker controller;
a shaker head expander;
a shaker amplifier;
a blower; and
an air float subsystem;
an equipment cabinet,
wherein the equipment cabinet is configured to store equipment to test the unit under test, and
wherein the equipment cabinet further comprises:
a digital multimeter;
an oscilloscope;
power conditioning equipment;
an air filter; and
a cooling system.

2. The device of claim 1, wherein the interface test adapter is configured to connect the intermittent failure analyzer modules to a unit under test to enable communication between the intermittent failure analyzer and test circuits in the unit under test.

3. The device of claim 2, wherein the intermittent failure analyzer modules are configured to measure voltage potential of conductive paths in the unit under testing.

4. The device of claim 3, wherein the intermittent failure analyzer is configured to signal the control computer when a voltage deviates from an expected value.

5. The device of claim 2, wherein:
the interface test adapter is configured to connect the unit under test to the intermittent failure analyzer; and
the interface test adapter is an inimitable interface adaptor.

6. The device of claim 1, wherein the intermittent failure analyzer is configured to detect:
steady-state electromechanical conductivity failure; and
intermittent electromechanical conductivity failure.

7. The device of claim 1, wherein the control computer is configured to:
receive input regarding relevant test parameters;
transfers the test parameters to an operative detection and isolation subsystem; and
display test results to the user.

8. A system comprising:
a control computer, wherein:
the control computer is configured to be a central control for system;
is configured to collect and analyze data associated with a unit under test; and
the control computer commands environmental stimuli to simulate real-world environmental conditions;
an intermittent failure analyzer,
an interface test adapter,
an environmental chamber, and
a shaker subsystem,
wherein the system is configured to:
conduct simultaneous real-time automated measurements of an amass of conductive paths within the unit under test to detect failure modes,
receive input regarding relevant test parameters,
transfer the test parameters to an operative detection and isolation subsystem, and
implement digital signal processing techniques to analyze the failure modes.

9. The system according to claim 8, wherein the digital signal processing techniques comprise:
signal response shape analysis,
comparative analysis,
historical analysis, and
trend analysis.

10. The system of claim 9, wherein the digital signal processing techniques are implemented to reduce an effect of background electrical and magnetic field effects on measurements.

11. The system of claim 8, wherein the system is configured to provide failure isolation techniques comprising:
adaptive directive current flow through a unit under test circuits,
voltage differential analysis of unit under test conductor paths, and
manual and automatic probing of unit under test circuits.

12. The system of claim 8, wherein the system is configured to:
collects test results comprising:
failure detection,
failure location, and
failure response data of a failure location in a circuit of a unit under test.

13. The system of claim 8, wherein the system is configured to:
capture and collect electromechanical failures detected from an amass of unit under test circuits comprising:
failure severity monitoring over time; and
failure trend data.

14. The system of claim 13, wherein the system:
organizes and tags collected results data with metadata,
wherein the metadata comprises:
unit under test serial number,
unit under test model number,
operator identification code,
operator geographic location,
time/date of detection, and
environmental stimulus applied.

15. A method comprising:
placing a unit under test in an environmental chamber and a environmental shaker,
wherein the unit under test is an electromechanical device,
wherein the environmental chamber comprises:
an environmental chamber control subsystem,
a heating ventilation and cooling controller; and
wherein the environmental shaker comprises:
a shaker subsystem,
a shaker amplifier;
a shaker controller;
a shaker head expander;
a blower; and
an air float subsystem;
attaching the unit under test to an intermittent failure analyzer, wherein:
the unit under test is attached to the intermittent failure analyzer via an interface test adapter;
the intermittent failure analyzer further comprises intermittent failure analyzer modules; and
the intermittent failure analyzer monitors circuits continuously;
testing the unit under test with environmental stimuli; and
receiving at a control computer data from the testing with environmental stimuli,
wherein the data is processed in the control computer and provided to a user via a graphical user interface.

16. The method of claim 15, further comprising:
measuring an amass of conductive paths within the unit under test to detect:
steady-state electromechanical conductivity failure;
intermittent electromechanical conductivity failure; or
inline passive component characteristics.

17. The method of claim 16, further comprising:
adjusting measured signal-to-noise ratio sensitivity; and
measuring electromechanical failure modes,
wherein the method further isolates electromechanical failures to a single circuit.

18. The method of claim 17, further comprising:
analyzing the electromechanical failure mode via digital signal processing comprising:
signal response shape analysis,
comparative analysis,
historical analysis, and
trend analysis.

19. The method of claim 18, further comprising:
using machine learning to analyze the electromechanical failure mode of a unit under test over time,
wherein the electromechanical failure mode comprises:
a number of electromechanical failure modes detected,
ambiguity group of electromechanical failure mode isolated,
analysis of electromechanical failure modes, and
electromechanical failure trends.

20. The method of claim 19, further comprising:
initiating commands to the environmental chamber,
initiating commands to the shaker subsystem, and
monitoring the testing in real-time via the graphical user interface.
